(19) United States
(12) Patent Application Publication
(10) Pub. No.: US 2014/0175553 A1
(43) Pub. Date: Jun. 26, 2014

(54) MOS SEMICONDUCTOR DEVICE AND METHOD OF MANUFACTURING THE SAME

(71) Applicant: KABUSHIKI KAISHA TOSHIBA, Tokyo (JP)

(72) Inventors: Toshitaka MIYATA, Yokkaichi-shi (JP); Masakazu GOTO, Yokohama-shi (JP); Akira HOKAZONO, Kawasaki-shi (JP)

(21) Appl. No.: 13/901,454

(22) Filed: May 23, 2013

(30) Foreign Application Priority Data
Dec. 21, 2012 (JP) 2012-279759

(51) Int. Cl. H01L 29/78; H01L 29/66

(52) U.S. Cl. CPC H01L 29/7831; H01L 29/66484
USPC 257/365; 438/283

(57) ABSTRACT

According to one embodiment, a MOS semiconductor device comprises a first gate insulating film formed on a region of part of a channel of a semiconductor substrate, in which a transistor is to be formed, a first gate electrode formed on the first gate insulating film, a second gate insulating film formed on remaining part of the channel, the second gate insulating film including an impurity added to the second gate insulating film to increase a threshold value of the channel immediately under the second gate insulating film, and a second gate electrode formed on the second gate insulating film.

### CROSS-REFERENCE TO RELATED APPLICATIONS

This application is based upon and claims the benefit of priority from Japanese Patent Application No. 2012-279759, filed Dec. 21, 2012, the entire contents of which are incorporated herein by reference.

### FIELD

Embodiments described herein relate generally to a MOS semiconductor device and a method of manufacturing the same.

### BACKGROUND

To scale down CMOS analog devices, channel-length modulation is an unavoidable problem. To solve the problem, dual work function field-effect transistors (DWF-FETs) have been developed. In DWF-FETs, two gate materials having different work functions are used and arranged in the channel-length direction. In the DWF-FET, it is possible to make a difference between channel potentials immediately under the gates, and thus increase, for example, the output resistance.

In the case of using materials of different work functions for the gate, however, the difference in work function depends on the materials, and cannot be variable. Thus, the degree of freedom for device design is low.

### BRIEF DESCRIPTION OF THE DRAWINGS

FIG. 1 is a cross-sectional view illustrating a schematic structure of a MOS semiconductor device according to a first embodiment.

FIG. 2 is a diagram illustrating energy potential in the semiconductor device of FIG. 1.

FIG. 3A to FIG. 3H are cross-sectional views illustrating a process of manufacturing the MOS semiconductor device illustrated in FIG. 1.

FIG. 4 is a cross-sectional view illustrating a schematic structure of a MOS semiconductor device according to a second embodiment.

FIG. 5A to FIG. 5D are cross-sectional views illustrating a process of manufacturing the MOS semiconductor device illustrated in FIG. 4.

### DETAILED DESCRIPTION

In general, according to one embodiment, a MOS semiconductor device comprises: a first gate insulating film formed on a region of part of a channel of a semiconductor substrate, in which a transistor is to be formed; a first gate electrode formed on the first gate insulating film; a second gate insulating film formed on remaining part of the channel, the second gate insulating film including an impurity added to the second gate insulating film to increase a threshold value of the channel immediately under the second gate insulating film; and a second gate electrode formed on the second gate insulating film.

MOS semiconductor devices according to embodiments will be explained hereinafter with reference to drawings.

### First Embodiment

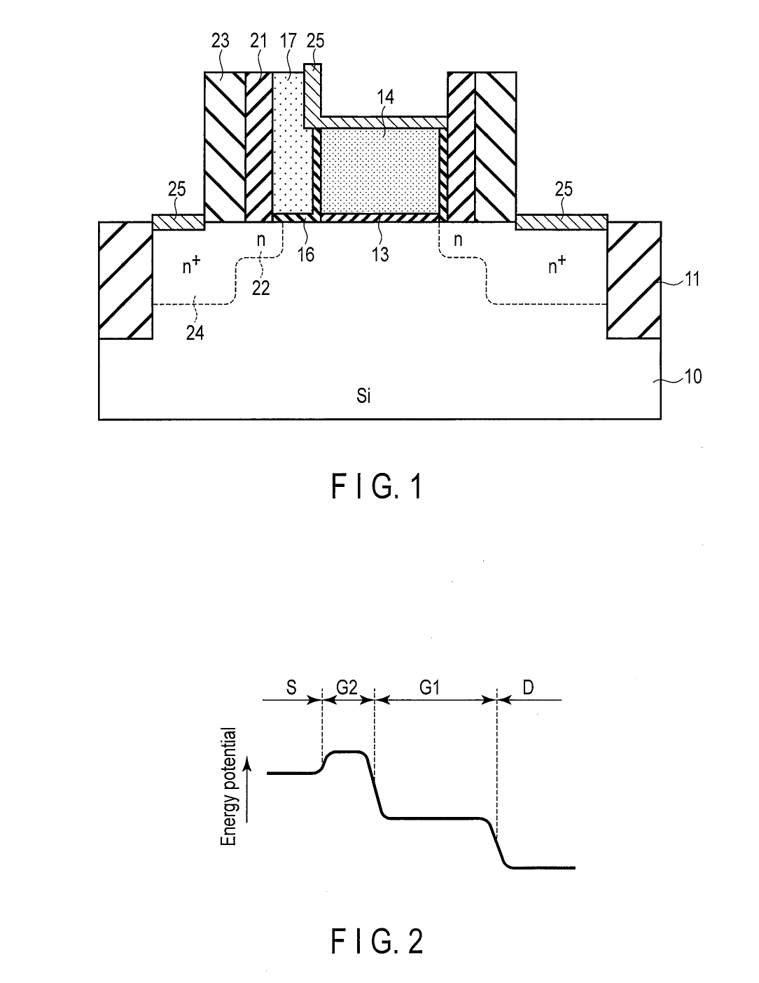

FIG. 1 is a cross-sectional view illustrating a schematic structure of a MOS semiconductor apparatus according to a first embodiment.

Device isolation regions 11 configured to electrically isolate individual devices are formed in a surface part of an Si substrate (semiconductor substrate) 10. A first gate electrode 14 is formed on a center part of a device formation region surrounded by the device isolation regions 11, with an SiO₂ first gate insulating film 13 interposed therebetween.

A second gate electrode 17 is formed on a side surface of the first gate electrode 14 and on a surface of the substrate 10, with a second gate insulating film 16 interposed therebetween. Impurities such as hafnium (Hf) are added to second gate insulating film 16. The gate insulating films 13 and 16 are formed of SiO₂, and the gate electrodes 14 and 17 are formed of polycrystalline Si.

First sidewall insulating films 21 are formed on both side surfaces of a gate part, which is formed of the first and second gate electrodes 14 and 17 and the first and second gate insulating films 13 and 16, and second sidewall insulating films 23 are formed on both side surfaces of the first sidewall insulating film 21. In addition, n-type extension diffusion layers 22 are formed in the surface part of the substrate 10, to hold the gate part therebetween. Besides, n+ source/drain diffusion layers 24 are formed outside the extension diffusion layers 22.

Silicide layers (conductor films) 25 serving as source/drain electrodes are formed on the source/drain diffusion layers 24 in the surface part of the substrate 10. Silicide layer 25 is also formed on the gate electrodes 14 and 17, and thereby the gate electrodes 14 and 17 are electrically short-circuited.

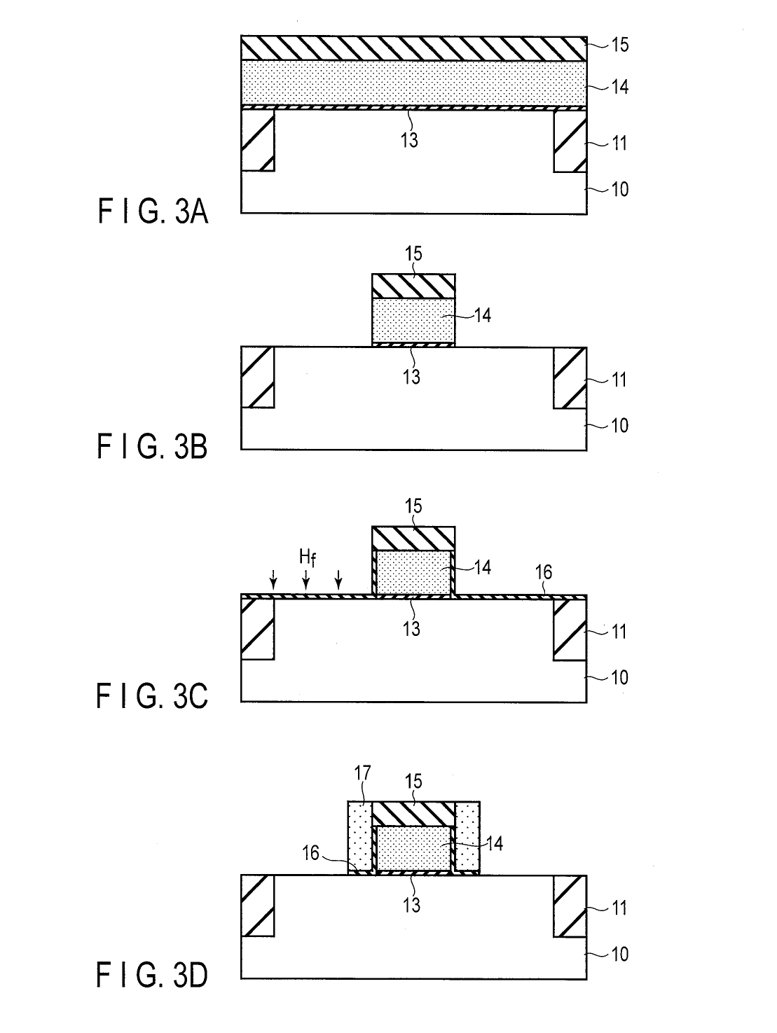

In the present embodiment, the gate part is formed of the gate insulating films 13 and 16 and the gate electrodes 14 and 17, and Hf is added to the second gate insulating film 16 formed of SiO₂. Thus, as illustrated in the energy potential diagram of FIG. 2, the potential of the channel immediately under the second gate electrode 17 has high value, and it is possible to provide a difference between the channel potential immediately under the first gate electrode 14 and the channel potential immediately under the second gate electrode 17. Specifically, even when the same material is used for the first and second gate electrodes 14 and 17, it is possible to obtain the same effect as that of a DWF-FET, in which materials of different work functions are used for the gate electrodes 14 and 17. In FIG. 2, reference symbol S is source, D is drain, G1 is the first gate electrode 14, and G2 is the second gate electrode 17.

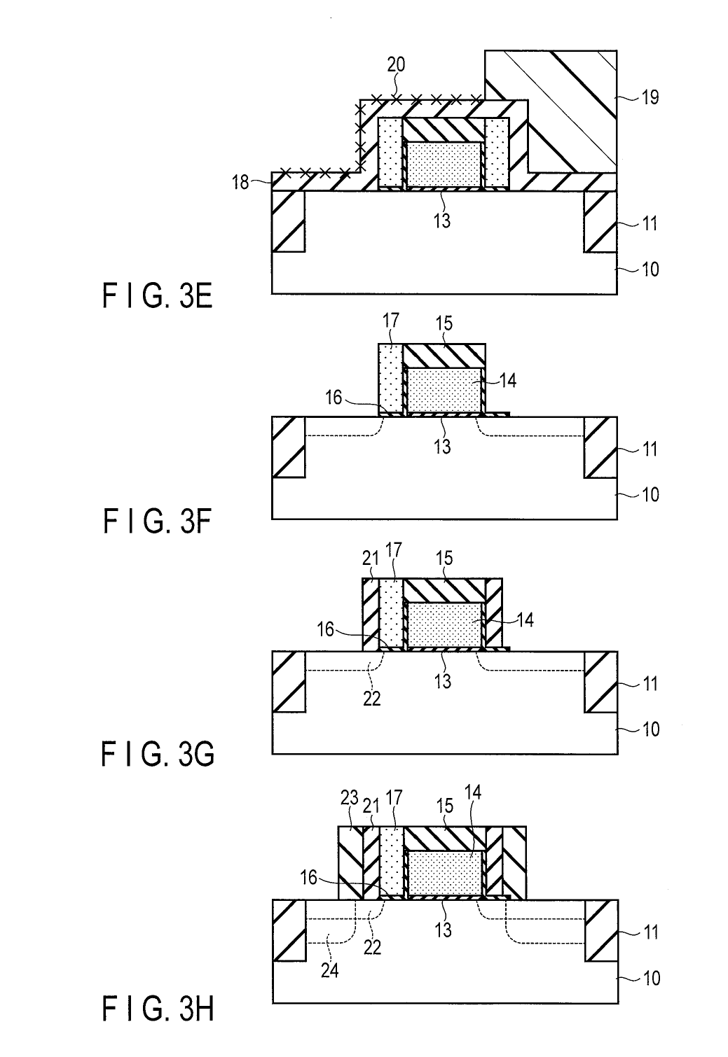

Next, a method of manufacturing the semiconductor device of the present embodiment will be explained hereinafter with reference to cross-sectional views of FIG. 3A to FIG. 3H.

First, as illustrated in FIG. 3A, device isolation regions 11 configured to electrically isolate individual devices and formed of SiO₂ are formed by, for example, shallow trench isolation (STI). Then, impurities to control the device threshold voltage are introduced into a device formation region surrounded by the device isolation regions 11, by ion implantation or the like. When an nMOS is formed, for example, boron (B) is doped as p-impurities.

Next, a first gate insulating film 13 formed of SiO₂ is formed with a thickness of 1.2 nm on the device formation region by, for example, thermal oxidation. In addition, polycrystalline Si serving as first gate electrode 14 is deposited with a thickness of 100 nm on the gate insulating film 13, and impurities are introduced into the polycrystalline Si layer in this state. When an nMOS is formed, for example, phosphor (P) is introduced by ion implantation. Thereafter, a hard mask 15 to protect the gate electrode 14 is deposited with a thickness of 50 nm by, for example, chemical vapor deposition (CVD). During this processing, for example, SiN is used as the hard mask 15.

Next, as illustrated in FIG. 3B, a stacked structure of the gate insulating film 13, the gate electrode 14, and the hard mask 15 is processed into a gate pattern by, for example, reactive ion etching (RIE), with a resist (not shown) used as mask. Specifically, the hard mask 15 is processed into a gate pattern with the resist used as mask, and the gate electrode 14 is subjected to selective etching by RIE. Then, the gate insulating film 13 exposed to the surface of the substrate is removed by wet etching.

Next, as illustrated in FIG. 3C, an SiO₂ film is formed with a desired thickness (for example, 1.2 nm) by thermal oxidation or the like, to form the second gate insulating film 16. In this processing, the SiO₂ film is formed not only on the surface of the substrate, but also side surfaces of the gate electrode 14. Thereafter, for example, Hf of 1×10¹⁴ atoms/cm² is added to the second gate insulating film 16 by sputtering or the like, to control the threshold value immediately under the second gate electrode 17. Adding Hf causes pinning of the band gap, and enables increase in the threshold value in the channel.

Next, as illustrated in FIG. 3D, 30 nm of P-doped Si is deposited by CVD in the nMOS, to form the second gate electrode 17. Thereafter, the second gate electrode 17 is etched back by using RIE or the like, and thereby the second gate electrode 17 is left only on the side surfaces of the first gate electrode 14. Thereby, the second gate electrode 17 is formed by self-alignment.

Next, as illustrated in FIG. 3E, for example, 10 nm of an SiN film 18 is deposited, to remove an unnecessary part of the second gate electrode 17, which is located on the drain side. In this state, a resist 19, which is cut on the gate part, is formed, such that the drain region is closed and the source region is opened. Then, an oxidized film region 20 is formed on the SiN film 18 on the source side by O₂-RIE or the like, with the resist 19 used as a mask.

Next, as illustrated in FIG. 3F, the resist 19 is removed, and then hot phosphoric acid is added in this state. Thereby, the SiN film 18 is left in the oxidized film region 20, and the SiN film 18 is removed by hot phosphoric acid in the other regions. In this state, only polycrystalline Si on the drain side is removed by choline hydroxide or the like. In this processing, the oxidized film region 20 on the source side is also removed.

Thereafter, the SiN film 18 used as a mask is removed by, for example, hot phosphoric acid. In this processing, the gate insulating film 16 exposed on the drain side may be removed by RIE or the like. FIG. 3F illustrates a state in which the gate insulating film 16 on the drain side is left.

Next, as illustrated in FIG. 3G, 5 nm of SiO₂ is deposited by CVD to form the first sidewall insulating films 21, and then the SiO₂ film is processed by RIE or the like. In this state, ion implantation is performed to form the source/drain extension diffusion layers 22. In this processing, when an nDWF-FET is formed, arsenic (As) is used for ion implantation, and ion implantation is performed under the conditions that the accelerating voltage is 1 keV and the dose is 1×10¹⁵ cm⁻².

Next, as illustrated in FIG. 3H, for example, 30 nm of SiO₂ is deposited by CVD, and then processed by RIE or the like, to form the second sidewall insulating films 23. In this state, ion implantation is performed to form deep source/drain diffusion layers 24. In this processing, in the case of forming an nDWF-FET, As is used for ion implantation, and ion implantation is performed under the conditions that the accelerating voltage is 20 keV and the dose is 3×10¹⁵ cm⁻². Thereafter, in anneal processing, spike anneal is performed at 1050° C. to activate the impurities introduced by ion implantation.

Then, the hard mask 15 is detached by using hot phosphoric acid, and thereafter a silicide layer 25 is formed on the source/drain diffusion layers 24 and the gate electrodes 14 and 17. Thereby, the structure illustrated in FIG. 1 is finished. In this processing, the first gate electrode 14 and the second gate electrode 17 are short-circuited by the silicide layer 25.

Thereby, it is possible to make the threshold value of the channel region immediately under the second gate electrode 17 different from the threshold value of the channel region immediately under the first gate electrode 14 in a discrete manner. In addition, it is possible to make a desired difference in work function, by adjusting the quantity of impurities added to the second gate insulating film 16. In this case, the second gate electrode 17 functions as effective gate.

As described above, according to the present embodiment, the first and second gate electrodes 14 and 17 are provided in the channel-length direction, and Hf is added to the second gate insulating film 16. Thereby, it is possible to make a difference in channel potential immediately under the gate between the gate electrodes. Specifically, it is possible to obtain a semiconductor device having the same effect as a DWF, although the gate electrodes are formed of the same gate material, and it is possible to make a difference in level of the channel potential immediately under the gate in a continuous manner. In this case, the difference in potential can be set to a desired value by adjusting the quantity of Hf to be added, instead of using different materials for the respective gate electrodes. Thus, it is possible to increase degree of freedom for device design.

In conventional DWF-FETs, too large a difference in work function between the first gate electrode and the second electrode easily causes impact ionization, while too small a difference in work function reduces the effect peculiar to DWFs. In comparison with this, according to the present embodiment, adjusting the quantity of Hf added to the second gate insulating film 16 is equivalent to selecting a proper difference in work function. Thus, the degree of freedom for device design is increased.

In addition, according to the present embodiment, the second gate electrode 17 substantially serving as gate is formed by a technique of leaving side walls, in a self-aligning manner. This structure provides an advantage of improvement in control of the gate length.

### Second Embodiment

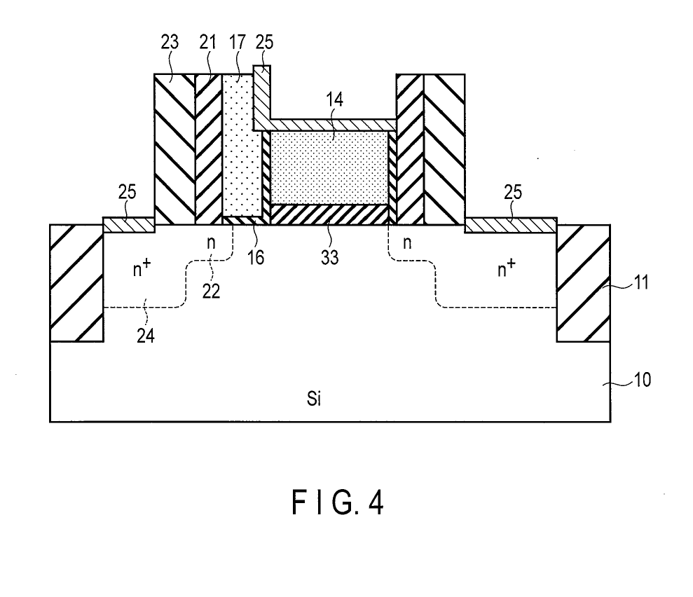

FIG. 4 is a cross-sectional view illustrating a schematic structure of a MOS semiconductor device according to a second embodiment.

The same constituent elements as those in the FIG. 1 are denoted by the same respective reference numbers, and detailed explanation thereof is omitted.

The second embodiment is different from the first embodiment described above in that a first gate insulating film 33 has a thickness greater than that of a second gate insulating film 16. Specifically, the second gate insulating film 16 has a thickness of 1.2 nm, which is equal to the thickness in the first embodiment, while the first gate insulating film 33 has a thickness of 3 nm, which is greater than that of the second gate insulating film 16.

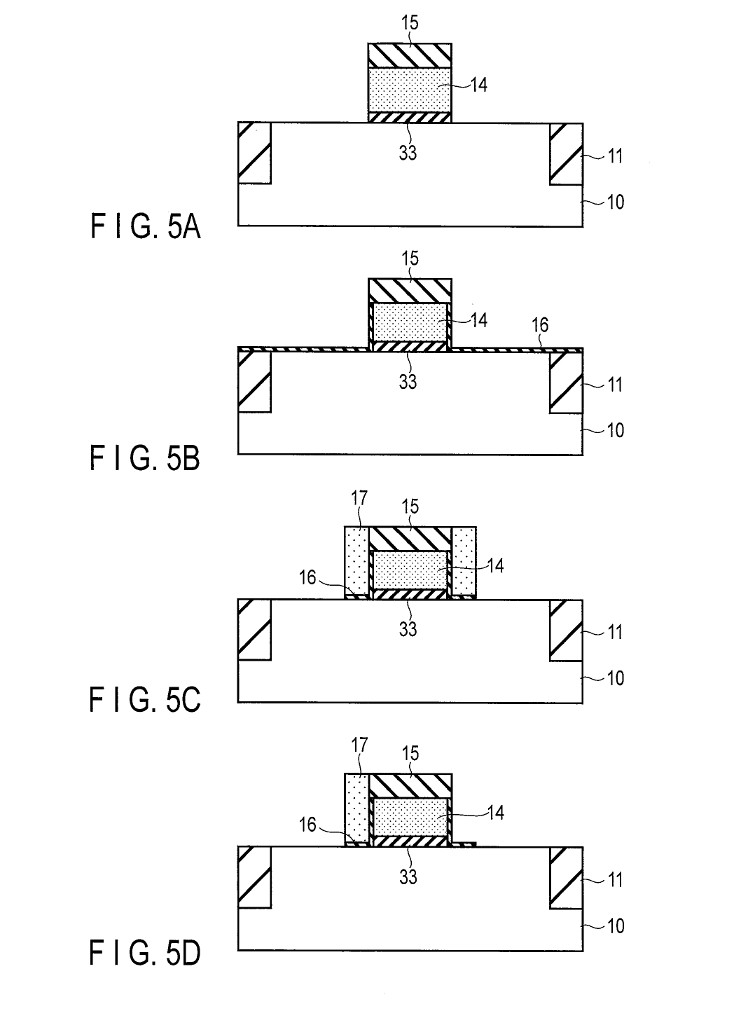

Next, a method of manufacturing a semiconductor device according to the present embodiment will be explained hereinafter with reference to cross-sectional views of FIG. 5A to FIG. 5D.

First, as illustrated in FIG. 5A, in the same manner as in the first embodiment, device isolation regions 11 are formed in a surface part of an Si substrate 10, and a stacked structure including a first gate insulating film 33 formed of SiO₂, a first gate electrode 14 formed of polycrystalline Si, and a hard mask 15 formed of SiN is formed on a device formation region. Then, the stacked structure is processed into a gate pattern. In the structure, the first gate insulating film 33 has a thickness greater than that of the second gate insulating film 16 formed later. For example, the first gate insulating film 33 has a thickness of 3 nm. The gate insulating film 33 having such a large thickness suppresses excessive gate leakage.

Next, as illustrated in FIG. 5B, in the same manner as in the first embodiment, the second gate insulating film 16 formed of SiO₂ is formed with a thickness of 1.2 nm by thermal oxidation. Then, for example, Hf of 1×10¹⁴ atoms/cm² is added by sputtering or the like, to control the threshold value immediately under the second gate insulating film 16.

Next, as illustrated in FIG. 5C, in the same manner as in the first embodiment, for example, P-doped Si in the case of forming an nMOS is deposited with a thickness of 30 nm by CVD, and thereafter processed by RIE or the like, to form a second gate electrode 17. Then, as illustrated in FIG. 5D, unnecessary part of the second gate electrode 17, which is located on the drain side, is removed.

Thereafter, sidewall insulating films 21 and 23, diffusion layers 22 and 24, and silicide layers 25 are formed in the same manner as in the first embodiment, and thereby the structure illustrated in FIG. 4 is finished.

As described above, according to the present embodiment, a gate part is formed of the first and second gate insulating films 33 and 16 and the first and second gate electrodes 14 and 17, and Hf is added to the second gate insulating film 16. Thus, like the first embodiment, it is possible to make a difference in level between the channel potential immediately under the first gate electrode 14 and the channel potential immediately under the second gate electrode 17. It is thus possible to obtain the same effect as that of the first embodiment.

In addition, in the present embodiment, the gate insulating film 33 contacting the first gate electrode 14 has a greater thickness, and thus the gate capacitance and the gate leakage are reduced. In the transistor structure of the present embodiment, the second gate electrode 17 functions as effective gate, and thus no problem with performance is caused by increasing the thickness of the second gate insulating film 33.

### Modification

The present invention is not limited to the above embodiments.

Although Hf is used as impurities added to the second gate insulating film in the embodiments, the impurities are not limited to it. Any impurities may be used, as long as they have an effect of increasing the threshold value of the channel when added to the insulating film. For example, it is possible to use Al or La as impurities. In addition, the quantity of impurities to be added can be determined in accordance with a desired difference in potential.

Although the embodiments show the case of adopting an nMOS, the present invention may be applied to a pMOS in the same manner as a matter of course. In the case of adopting a pMOS, the impurities added to the gate insulating film may be the same as those used for an nMOS.

In addition, the gate insulating films are not limited to SiO₂, but other insulating films may be used. The thicknesses of the first and second gate insulating films can be changed according to specifications. Besides, the material of the gate electrodes is not limited to polycrystalline Si, but any material may be used as long as it is a conductor. For example, the gate electrodes may be formed of metal.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A MOS semiconductor device, comprising:
a first gate insulating film formed on a region of part of a channel of a semiconductor substrate, in which a transistor is to be formed;
a first gate electrode formed on the first gate insulating film;
a second gate insulating film formed on remaining part of the channel, the second gate insulating film including an impurity added to the second gate insulating film to increase a threshold value of the channel immediately under the second gate insulating film; and
a second gate electrode formed on the second gate insulating film.

2. The device of claim 1, wherein
the impurity added to the second gate insulating film is Hf, Al, or La.

3. The device of claim 1, wherein
the first and second gate insulating films are formed of SiO₂.

4. The device of claim 1, further comprising:
a silicide layer formed on the first and second gate electrodes,
wherein the first and second gate electrodes are short-circuited by the silicide layer.

5. The device of claim 1, wherein
the second gate electrode is formed on one side part of the first gate electrode.

6. The device of claim 1, wherein
the first and second gate electrodes are formed of polycrystalline Si.

7. The device of claim 1, wherein
sidewall insulating films are formed on both side parts of a gate module formed of the first and second gate electrodes, extension layers are formed in surface parts of the semiconductor substrate immediately under the sidewall insulating films, and source/drain regions are formed in surface parts of the semiconductor substrate, the source/drain regions located outside the extension regions.

8. A MOS semiconductor device, comprising:
a first gate insulating film formed on a region of part of a channel of a semiconductor substrate, in which a transistor is to be formed;
a first gate electrode formed on the first gate insulating film;
a second gate insulating film formed on remaining part of the channel and having a thickness less than that of the first gate insulating film, the second gate insulating film including an impurity added to the second gate insulating film to increase a threshold value of the channel immediately under the second gate insulating film; and
a second gate electrode formed on the second gate insulating film.

9. The device of claim 8, wherein
the impurity added to the second gate insulating film is Hf, Al, or La.

10. The device of claim 8, wherein
the first and second gate insulating films are formed of SiO₂.

11. The device of claim 8, further comprising:
a silicide layer formed on the first and second gate electrodes,
wherein the first and second gate electrodes are short-circuited by the silicide layer.

12. The device of claim 8, wherein
the second gate electrode is formed on one side part of the first gate electrode.

13. The device of claim 8, wherein
the first and second gate electrodes are formed of polycrystalline Si.

14. The device of claim 8, wherein
sidewall insulating films are formed on both side parts of a gate module formed of the first and second gate electrodes, extension layers are formed in surface parts of the semiconductor substrate immediately under the sidewall insulating films, and source/drain regions are formed in surface parts of the semiconductor substrate, the source/drain regions located outside the extension regions.

15. A method of manufacturing a MOS semiconductor device, comprising:
forming a first gate electrode on a region of part of a channel of a semiconductor substrate, with a first gate insulating interposed between the first gate electrode and the region, in which a transistor is to be formed;
forming a second gate insulating film on remaining part of the channel,
adding an impurity to the second gate insulating film to increase a threshold value of the channel immediately under the second gate insulating film; and
forming a second gate electrode on the second gate insulating film, to which the impurity has been added.

16. The method of claim 15, wherein
Hf, Al, or La is used as the impurity added to the second gate insulating film.

17. The method of claim 15, wherein
SiO₂ is used as the first and second gate insulating films.

18. The method of claim 17, wherein
the forming the second gate insulating film is forming the second gate insulating film with a thickness less than that of the first gate insulating film.

19. The method of claim 15, further comprising:
forming a silicide layer on the first and second gate electrodes, to electrically connect the electrodes,
wherein the first and second gate electrodes are formed of polycrystalline Si.

20. The method of claim 15, wherein forming the second gate electrode comprises:
forming a polycrystalline Si film on both sides of the first gate electrode;
subsequently forming a nitride film to cover the first gate electrode and the polycrystalline Si film;
subsequently forming an oxide film region on the nitride film located on one side of the first gate electrode;
subsequently removing the nitride film from another side where the oxide film region is not formed; and
etching the polycrystalline Si film, using a remaining portion of the nitride film as a mask.
